(19) United States
(12) Patent Application Publication
(10) Pub. No.: US 2007/0166855 A1
(43) Pub. Date: Jul. 19, 2007

(54) Display device and method of manufacturing the same

(76) Inventors: Yong-uk Lee, Seongnam-si (KR); Soo-jin Kim, Suwon-si (KR); Joon-hak Oh, Yongin-si (KR)

Correspondence Address: CANTOR COLBURN, LLP, 55 GRIFFIN ROAD SOUTH, BLOOMFIELD, CT, 06002, US

(21) Appl. No.: 11/534,106

(22) Filed: Sep. 21, 2006

(30) Foreign Application Priority Data
Sep. 21, 2005 (KR) 2005-0087520

(51) Int. Cl. H01L 21/00; H01L 29/08; H01L 29/04; H01L 33/00

(52) U.S. Cl. 438/29; 257/40; 257/59; 257/103

(57) ABSTRACT

A display device comprises an insulating substrate, an organic semiconductor layer formed on the insulating substrate, a source electrode and a drain electrode, wherein the source electrode and the drain electrode are interposed between the insulating substrate and the organic semiconductor layer, and spaced away from each other to define a channel region therebetween which is biased to one side of a region in which the organic semiconductor layer is formed.

This application claims priority to Korean Patent Application No. 2005-0087520, filed on Sep. 21, 2005, and all the benefits accruing therefrom under 35 U.S.C. §119, and the contents of which in its entirety are herein incorporated by reference.

### BACKGROUND OF THE INVENTION

1. Field of the Invention

The present invention relates to a display device, and more particularly, to a display device including an organic semiconductor layer, and a method of manufacturing the same.

2. Description of the Related Art

Flat display devices are gaining popularity thanks to their advantageous features such as compactness and light weight. Such flat display devices include liquid crystal displays (“LCDs”) and organic light emitting diode (“OLED”) displays. Both devices include a substrate on which a thin film transistor is disposed. For example, the LCD includes a liquid crystal panel having a thin film transistor substrate on which a thin film transistor is formed, a color filter substrate on which a color filter layer is formed, and a liquid crystal layer disposed between the thin film transistor layer and the color filter substrate. As the liquid crystal panel is a non light-emitting device, a backlight unit for providing light may be located on a rear surface of the thin film transistor substrate. The transmittance of the light from the backlight unit through the liquid crystal panel is adjusted by arrangement of the liquid crystal layer.

Herein, the thin film transistor (“TFT”) acts as a switching and driving device controlling and driving the operation of each pixel. The TFT includes a semiconductor layer, which is usually made of amorphous silicon or poly silicon. Application of an organic semiconductor (“OSC”) to the semiconductor layer is a relatively new and promising technique. Because OSC can be formed at room temperature and atmospheric pressure OSC provides several advantages such as a reduction of manufacturing cost and applicability to plastics that are vulnerable to heat. Thus, a TFT to which the OSC is applied shows potential as a driving device of the next generation of large screen, mass-produced displays.

Such an OSC can be formed by a simple ink-jet method without performing developing processes like spin coating, exposing, etc. When the OSC is formed by such an ink-jet method, a bank surrounding a part in which the OSC is located is required, and an organic semiconductor solution is then jetted into the depression formed by the bank.

However, after hardening, the organic semiconductor solution jetted in the bank is formed into a shape whose central region is lower in height than the surrounding peripheral region. This effect is due to a difference in an evaporation speed of the organic semiconductor solution; the evaporation speed is greater in the peripheral region than in the central region, thus making the peripheral region thicker than the central region. The drawback to such a difference in thickness is an organic thin film transistor with non-uniform electrical characteristics.

### BRIEF SUMMARY OF THE INVENTION

One aspect of the present invention is to provide a display device including a thin film transistor having uniform electrical characteristics.

Further, it is another aspect of the present invention to provide a method of manufacturing a display device including a thin film transistor having uniform electrical characteristics.

An exemplary embodiment of the present invention includes a display device including an insulating substrate, an organic semiconductor layer formed on the insulating substrate, a source electrode, and a drain electrode, wherein the source electrode and the drain electrode are interposed between the insulating substrate and the organic semiconductor layer. The source and drain electrodes are spaced apart from each other to define a channel region therebetween. The channel region is located with a bias to one side of a region in which the organic semiconductor layer is formed.

According to an exemplary embodiment of the present invention, the display device further includes a bank formed on the source electrode and the drain electrode. An opening, defined as the region interior to the banks, is formed which exposes the channel region. The channel region is formed so as to be located with a bias to one side of the opening, and the organic semiconductor layer is formed in the opening.

According to an exemplary embodiment of the present invention, the source electrode and the drain electrode are formed substantially parallel with each other and each extend in a direction in the region in which the organic semiconductor layer is formed. The source electrode and the drain electrode extend substantially perpendicular to an extension direction of extensions extending from the respective source and drain electrodes.

According to an exemplary embodiment of the present invention, the organic semiconductor layer includes a peripheral portion formed adjacent to the bank and a depressed portion surrounded by the peripheral portion and lower in height than the peripheral portion, and the channel region is formed within at least one region of the peripheral portion.

According to an exemplary embodiment of the present invention, a surface of the peripheral portion may be substantially flat.

According to an exemplary embodiment of the present invention, the organic semiconductor layer may be formed by either one of an ink-jet method and an evaporation method.

According to an exemplary embodiment of the present invention, the display device may further include a light-blocking layer located, corresponding to the organic semiconductor layer, between the insulating substrate and the source electrode and between the insulating substrate and the drain electrode. This exemplary embodiment also includes an interposing insulating layer covering the light-blocking layer.

According to an exemplary embodiment of the present invention, the display device further includes an organic insulating layer covering the organic semiconductor layer, and a gate electrode formed on the organic insulating layer.

According to an exemplary embodiment of the present invention, the display device further includes a gate electrode located between the insulating substrate and the source electrode and between the insulating substrate and the drain electrode, and a gate insulating layer covering the gate electrode.

Another exemplary embodiment of the present invention includes a display device including an insulating substrate, an organic semiconductor layer formed on the insulating substrate, a drain electrode and a source electrode interposed between the insulating substrate and the organic semiconductor layer. In this exemplary embodiment the drain electrode is extended from one direction to be expanded in width in a region in which the organic semiconductor layer is formed, the source electrode is extended from the other direction and formed along a periphery of the drain electrode and spaced away from the periphery of the drain electrode, and a channel region defined as a gap formed between the source electrode and the drain electrode is biased to one side of the region in which the organic semiconductor layer is formed.

According to an exemplary embodiment of the present invention, the display device further includes a bank formed on the source electrode and the drain electrode. An opening, defined as the region interior to the banks, is formed which exposes the channel region. The channel region is formed so as to be located with a bias to one side of the opening, and the organic semiconductor layer is formed in the bank opening.

According to an exemplary embodiment of the present invention, the channel region is located in a space formed between the bank and the drain electrode.

According to an exemplary embodiment of the present invention, the organic semiconductor layer includes a peripheral portion formed adjacent to the bank and a depressed portion surrounded by, and lower in height than, the peripheral portion. The channel region is formed corresponding to the peripheral portion in at least a portion of the peripheral portion.

According to an exemplary embodiment of the present invention, a surface of the peripheral portion may be substantially flat.

According to an exemplary embodiment of the present invention, the display device further includes a light-blocking layer located, corresponding to the organic semiconductor layer, between the insulating substrate and the source electrode and between the insulating substrate and the drain electrode. This exemplary embodiment also includes an interposing insulating layer covering the light-blocking layer.

According to an exemplary embodiment of the present invention, the display device further includes an organic insulating layer covering the organic semiconductor layer, and a gate electrode formed on the organic insulating layer.

Anther exemplary embodiment of the present invention includes a display device comprising an insulating substrate, a source electrode and a drain electrode spaced away from each other to define a channel region, a bank exposing at least one portion of the source electrode and at least one portion of the drain electrode and surrounding the channel region, and an organic semiconductor layer formed in the bank. In this exemplary embodiment the surface of the organic semiconductor layer corresponding to the channel region is flat.

According to an exemplary embodiment of the present invention, the organic semiconductor layer includes a peripheral portion formed adjacent to the bank and a depressed portion surrounded by, and lower in height than, the peripheral portion. The channel region is formed corresponding to the peripheral portion in at least a portion of the peripheral portion.

According to an exemplary embodiment of the present invention, the organic semiconductor layer includes a peripheral portion formed adjacent to the bank and a depressed portion surrounded by, and lower in height than, the peripheral portion. The channel region is formed corresponding to the depressed portion in at least a portion of the depressed portion.

According to an exemplary embodiment of the present invention, the drain electrode is formed in a region corresponding to the depressed portion, and the source electrode is formed along a periphery of the drain electrode and in the peripheral portion of the OCD.

According to an exemplary embodiment of the present invention, the drain electrode is formed in a region corresponding to the depressed portion, and the source electrode is formed in a region along a periphery of the drain electrode and in the periphery portion of the OCD.

The foregoing and/or other aspects of the present invention may be achieved by an exemplary embodiment of a method of manufacturing a display device. The method includes preparing an insulating substrate, forming a source electrode and a drain electrode which are spaced away from each other to define a channel region therebetween, forming a bank which exposes at least one portion of the source electrode and at least one portion of the drain electrode and surrounds the channel region, and forming an organic semiconductor layer in the bank, with a surface of the organic semiconductor layer corresponding to the channel region being substantially flat.

According to an exemplary embodiment of the present invention, the organic semiconductor layer includes a peripheral portion formed adjacent to the bank and a depressed portion surrounded by, and lower in height than the peripheral portion.

According to an exemplary embodiment of the present invention, the source electrode and the drain electrode are formed such that the channel region is located in at least a portion of the peripheral portion.

According to another exemplary embodiment of the present invention, the source electrode and the drain electrode are formed such that the channel region is located in at least a portion of the depressed portion.

According to another exemplary embodiment of the present invention, the drain electrode is formed in a region corresponding to the depressed portion, and the source electrode is formed along a periphery of the drain electrode and in the periphery portion of the OCD.

According to an exemplary embodiment of the present invention, the organic semiconductor layer may be formed by either one of an ink-jet method or an evaporation method.

According to an exemplary embodiment of the present invention, the method of manufacturing a display device further includes forming an organic insulating layer on the organic semiconductor layer using an ink-jet method, and forming a gate electrode on the organic insulating layer.

According to an exemplary embodiment of the present invention, the method of manufacturing a display device further includes forming a light-blocking layer, corresponding to the organic semiconductor layer, between the insulating substrate and the source electrode and between the insulating substrate and the drain electrode, and forming an interposing insulating layer covering the light-block layer.

According to an exemplary embodiment of the present invention, the method of manufacturing a display device further includes forming a gate electrode between the insulating substrate and the source electrode and between the insulating substrate and the drain electrode. Such an exemplary embodiment also includes forming a gate insulating layer covering the light-block layer.

According to an exemplary embodiment of the present invention, the method of manufacturing a display device further includes forming a passivation layer on the organic semiconductor layer using an ink-jet method.

### BRIEF DESCRIPTION OF THE DRAWINGS

The above and/or other aspects and advantages of the present invention will become apparent and more readily appreciated from the following description of the exemplary embodiments, taken in conjunction with the accompany drawings, in which:

FIGS. 1A and 1B are cross-sectional views illustrating a polymer solution drying on a substrate;

FIG. 2 is a cross-sectional view illustrating main parts of an exemplary embodiment of a display device according to the present invention;

FIG. 3 is a schematic top plan view of section ‘C’ shown in FIG. 2;

FIG. 4 is a partial cross-sectional view taken along line II-II of FIG. 3 illustrating the exemplary display device according to the present invention when a coffee stain phenomenon occurs;

FIGS. 5A through 5G depict cross-sectional views sequentially showing an exemplary method of manufacturing the display device when the coffee stain phenomenon occurs;

FIG. 6 is a schematic top plan view of section ‘C’ shown in FIG. 2 according to an alternative exemplary embodiment of the present invention; and

FIG. 7 is a cross-sectional view of another exemplary embodiment of a display device according to the present invention.

### DETAILED DESCRIPTION OF THE INVENTION

The invention will now be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present there between. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will be described in detail with reference to the accompanying drawings.

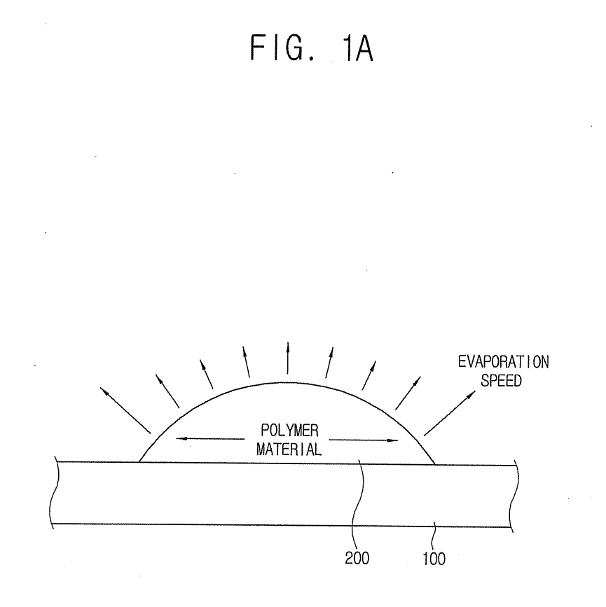

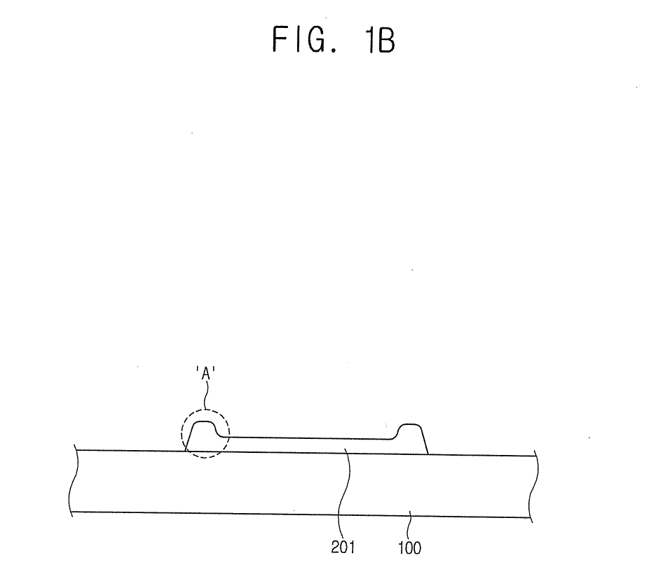

First, a problem concerned with drying of a polymer solution will now be described with reference to FIGS. 1A and 1B.

When manufacturing a display device using an ink-jet method, an organic polymer layer is formed by dissolving a prepared polymer solution in a solvent. The organic polymer layer includes, for example, an organic semiconductor layer of a thin film transistor, a hole-injection layer or a light-emitting layer of an organic light emitting diode (“OLED”) and may measure from several tens of nanometers to several hundreds of nanometers in thickness.

FIG. 1A shows polymer solution 200 dropped on an insulating substrate 100. FIG. 1B shows an organic polymer layer 201 formed by removing solvent from the polymer solution 200.

In FIG. 1A the polymer solution 200 has a shape whose thickness is greater at its central portion than at its peripheral portion due to surface tension. Vapor density of the solvent in the polymer solution 200 is greater in the central portion than in the periphery portion. Since drying speed of the solvent is inversely proportional to the vapor density of air around the polymer solution 200, the drying of the solvent occurs more rapidly at the peripheral portion than at the central portion. In FIG. 1B, the polymer material of the polymer solution 200 moves to the periphery portion where the drying of the solvent occurs more rapidly. The organic polymer layer 201 formed by this process has a shape whose thickness is greater at its periphery portion “A” than at its central portion. This phenomenon is known as a coffee stain phenomenon.

When the organic polymer layer 201 has a shape as shown in FIG. 1B, there is a problem that the non-uniform organic semiconductor layer results in non-uniform electrical characteristics of the thin film transistor.

The present invention improves the configuration of a source electrode and a drain electrode to solve the aforementioned problem occurring in the organic semiconductor layer.

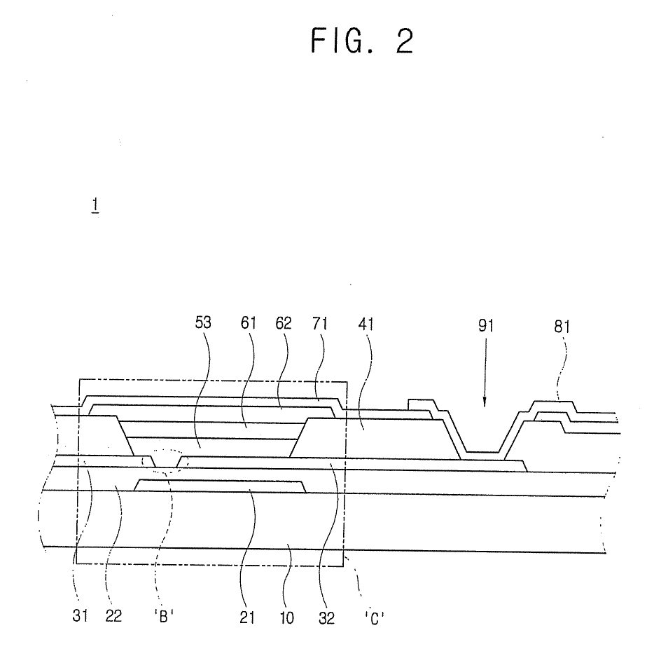

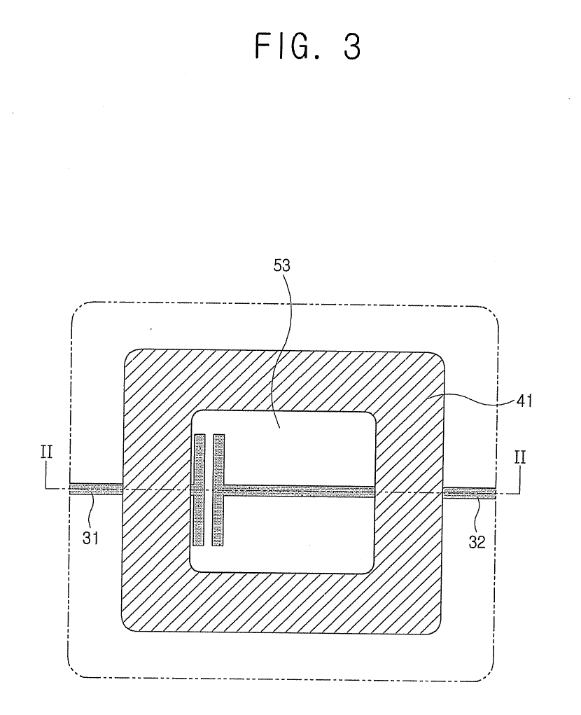

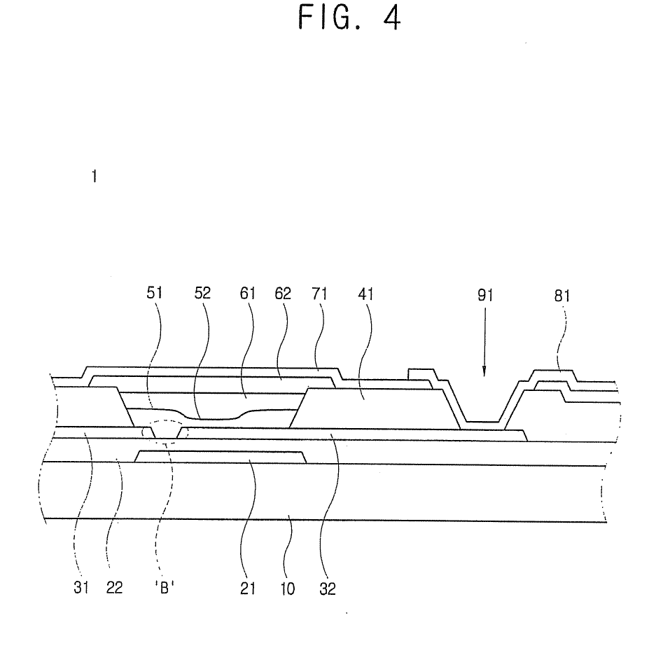

FIG. 2 is a cross-sectional view of main parts of an exemplary embodiment of a display device according to the present invention. FIG. 3 is a schematic top view of section ‘C’ shown in FIG. 2. FIG. 4 is a cross-sectional view of the main parts of the exemplary embodiment of the display device according to the present invention when the coffee-stain phenomenon occurs therein.

As shown in FIG. 2, a display device 1 according to the present invention includes an insulating substrate 10, a source electrode 31 and a drain electrode 32 which are formed on the insulating substrate 10 and spaced away from each other, a bank 41 which makes an opening which exposes a portion of the source electrode 31 and a portion of the drain electrode 32, and an organic semiconductor layer 53, or 51 and 52 formed interior to the bank 41.

The insulating substrate 10 may be made of glass or plastic. In the case where the insulating substrate 10 is made of plastic, the display device 1 can be advantageously elastic but disadvantageously becomes vulnerable to heat. The organic semiconductor layer 53, or 51 and 52 can be formed at room temperature and atmospheric pressure, and thus the insulating substrate 10 made of plastic may readily be used. The plastic may be selected from a group consisting of polycarbon, polyimide, polyethersulfone (PES), polyarylate (PAR), polyethylene naphthalate (PEN), and polyethylene terephthalate (PET).

A light-blocking layer 21 is formed on the insulating substrate 10. An interposing insulating layer 22 is formed on top of the light-blocking layer 21. The thin film transistor of the first exemplary embodiment is of a top-gate type in which a gate electrode 62 is disposed on the organic semiconductor layer 53, or 51 and 52. Therefore, the gate electrode 62 cannot prevent light incident on a lower surface of the insulating substrate 10 from being incident on the organic semiconductor layer 53, or 51 and 52. When the organic semiconductor layer 53, or 51 and 52 is exposed to light, its characteristics are changed, thus resulting in non-uniform performance of the thin film transistor. In this exemplary embodiment the light-blocking layer 21 prevents such non-uniform performance. The light-blocking layer 21 may be made of an opaque material such as Cr or MoW. In the case where the display device 1 is a liquid crystal display, the light incident on the lower surface of the insulating substrate 10 may be one emitted from a backlight unit. In the present embodiment, the light-blocking layer 21 masks the entire organic semiconductor layer 53, or 51 and 52. However, even if the light-blocking layer 21 masks only a portion of the organic semiconductor layer 53, or 51 and 52 as long as it blocks the channel region B it has a great effect on the characteristics of the thin film transistor.

The interposing insulating layer 22 disposed on the light-blocking layer 21 prevents the light-blocking layer 21 from acting as a floating electrode and flattens the light-blocking layer 21. The interposing insulating layer 22 should have high light transmission characteristics and should remain stable throughout the manufacturing process of the display. The interposing insulating layer 22 may be an organic layer made of benzo-cyclo-butene (BCB) and the like, an acryl-based photosensitive layer or a double layer of an organic and an inorganic layer. In a case of the double layer of the organic and the inorganic layer, the inorganic layer may include a silicon nitride layer with a thickness of several hundred angstroms (Å), which prevents introduction of impurities into the organic semiconductor layer 53, or 51 and 52 from the interposing insulating layer 22. It is preferable that the interposing insulating layer 22 remains stable in the semiconductor process and should be made of a material with high light transmission characteristics.

The source electrode 31 and the drain electrode 32 are formed on the interposing insulating layer 22. The source and drain electrodes are spaced away from each other by a predetermined distance, and a gap therebetween forms a channel region ‘B’. The source electrode 31 and the drain electrode 32 in a region in which the organic semiconductor layer 53, or 51 and 52 is formed extend in a direction substantially perpendicular to an extension direction of extensions of the source electrode 31 and the drain electrode 32. The source electrode 31 and the drain electrode 32 may be formed through a deposition and a photolithography process. The source electrode 31 and the drain electrode 32 are interposed between the insulating substrate 10 and the bank 41, and are formed such that the channel region “B” is biased to one side of an opening formed by the bank 41 (to be described later). That is, the channel region B may be formed so as to be biased in location to one side of the region in which the organic semiconductor layer 53, or 51 and 52 is formed.

It is preferable that the channel region ‘B’ is formed so as to be located in a region where the surface of the organic semiconductor layer 53, or 51 and 52 (to be described later) is substantially flat. If thickness of the organic semiconductor layer 53, or 51 and 52 varies along the channel region B, an organic TFT may show non-uniform electric characteristics due to that thickness difference. The source electrode 31 and the drain electrode 32 may be made of ITO (indium tin oxide), IZO (indium zinc oxide), or metal such as Cu, Mo, Ta, Cr, Ti, Al, Al alloy or the like.

The bank 41 is formed on the source electrode 31, the drain electrode 32 and a portion of the interposing insulating layer 22 that is not covered by either electrode. The bank 41 creates an opening by enclosing an area, defined on all sides by the banks 41. The opening leaves the channel region “B” and at least a portion of the source electrode 31 and at least a portion of the drain electrode 32 exposed. The bank 41 serves as a frame for forming the organic semiconductor layer 53, or 51 and 52. When the organic semiconductor is dripped, a drop of the organic semiconductor may be oversized or may not fall onto an accurate position, and drops of the organic semiconductor may be different in size. Such cases lead to a difference in extent of spreading of the organic semiconductor, which in turn results in non-uniform formation of the organic semiconductor layer 53, or 51 and 52. The bank 41 is formed to avoid such problems. That is, by preparing, in advance, a position onto which an ink drop is to fall, an ink-jet process can be performed precisely.

The bank 41 may be made of fluorine-based polymer. It is advantageous in dripping the ink in a desired position to select the bank 41 to be hydrophobic when the ink dripped in the bank 41 is hydrophilic and to select the bank 41 to be hydrophilic when the ink is hydrophobic. The fluorine-based polymer has features of water repellency and oil repellency. Although not limited to this, the fluorine-based polymer may include PTFE (Poly Tetra Fluoro Ethylene), FEP (Fluorinated Ethylene Propylene), PFA (Poly Fluoro Alkoxy), ETFE (Ethylene Tetra Fluoro Ethylene) and PVDF (Polyvinylidene Fluoride).

As shown in FIG. 2, the bank 41 surrounding the channel region B has a shape whose width is gradually narrowed towards its upper end, and may measures about 2.7 μm in height. The bank 41 is provided with a contact hole formed therein, which exposes the drain electrode 32. When the bank 41 is photosensitive, it may be formed through a coating, exposing and a developing process. If not photosensitive it may be formed through a photolithography process using a separate photosensitive layer after the coating process.

The organic semiconductor layer 53, or 51 and 52 is located in the opening created by the bank 41 and covers the channel region B, and the portions of the source electrode 31, and the drain electrode 32 which were exposed therein. The organic semiconductor layer 53, or 51 and 52 is formed by an ink-jet method, and made of a polymer or a low molecular weight material that can dissolve in a water solution or an organic solvent. Polymer organic semiconductor is especially suitable for an ink-jet process as it is usually dissolved well in a solvent. However, some of the low molecular weight materials, which can be dissolved well in the organic solvent, may also be used.

As shown in FIG. 4, the organic semiconductor layer 51 and 52 formed by the ink-jet method may include a peripheral portion 51 formed adjacent to the bank 41 and a depressed portion 52 surrounded by the peripheral portion 51 and lower in height than the peripheral portion 51. Surfaces of the peripheral portion 51 and the depressed portion 52 are comparatively flat, while an intermediate portion of the organic semiconductor between the peripheral portion 51 and the depressed portion 52 is slanted. This phenomenon, known as the coffee stain phenomenon, results from a difference in the evaporation speeds on a surface of an organic semiconductor solution during hardening. In general, the channel region ‘B’ is formed so as to be located in the bank 41 or at a front center portion of the organic semiconductor layer 51 and 52 when viewed from the top. In this case, the channel region ‘B’ is located in a region where a thickness difference occurs in the organic semiconductor layer 53, or 51 and 52. In such a structure or a configuration, there is a problem that the thin film transistor has non-uniform electrical characteristics.

In the present invention, to solve the aforementioned problem, the source electrode 31 and the drain electrode 32 are patterned such that the channel region ‘B’ is located in a region where the thickness difference does not occur in the organic semiconductor layer 53, or 51 and 52. That is, as shown in FIG. 4, the source electrode 31 and the drain electrode 32 are formed such that the channel region ‘B’ is located corresponding to the peripheral portion 51 of the organic semiconductor layer 53, or 51 and 52. Accordingly, the source electrode 31 and the drain electrode 32 are formed such that the channel region ‘B’ is biased to one side of the opening.

Alternatively, as another exemplary embodiment (not shown) the source electrode 31 and the drain electrode 32 are formed corresponding to the depressed portion 52 such that the channel region ‘B’ is located in at least a portion of the depressed portion 52. Herein, the surfaces of the organic semiconductor layer 51 and the 52 are comparatively flat. As a result, the channel region ‘B’ is disposed in a lower portion of the organic semiconductor layer 51 and 52 whose surface is comparatively flat, and thus the thin film transistor has uniform electrical characteristics.

The organic semiconductor layer 53, or 51 and 52 may be made of a derivative including a substituent of tetracene or pentacene; oligothiophene formed by connecting connection location number 2 and 5 of 4 to 8 thiophene ring.

Further, the organic semiconductor layer 53, or 51 and 52 may be made of perylenetetracarboxylic dianhydride (PTCDA), imide derivative of PTCDA, napthalenetetracarboxylic dianhydride (NTCDA), or imide derivative of NTCDA.

Further, the organic semiconductor layer 53, or 51 and 52 may be made of metalized pthalocyanine, derivative halide of metalized pthalocyanine, perylene, coronene, or a derivative including a substituent of a polymer or coronene, wherein it is preferable that a metal used in metalized pthalocyanine includes copper, cobalt, zinc or the like.

Further, the organic semiconductor layer 53, or 51 and 52 may be made of a co-oligomer or co-polymer of thienylene and vinylene.

The organic semiconductor layer 53, or 51 and 52 may be made of thienylene, coronene, a derivative including a substituent of thienylene and coronene, a derivative including one or more of a hydrocarbon chain having one to thirty carbons in an aromatic or heteroaromatic ring of the derivative including a substituent of thienylene and coronene.

An organic insulating layer 61 is formed on the organic semiconductor layer 53, or 51 and 52. If the organic semiconductor layer 53, or 51 and 52 is in contact with the gate electrode 62 or an inorganic insulating layer is interposed therebetween, characteristics of the organic semiconductor layer 53, or 51 and 52 would be deteriorated. The organic insulating layer 61 prevents direct contact of the organic semiconductor layer 53, or 51 and 52 and the gate electrode 62, and allows the characteristics of the organic semiconductor layer 53, or 51 and 52 to be maintained. The ink-jet method of forming the organic semiconductor layer 53, or 51 and 52 allows it to be slightly lower in height than the bank 41.

The gate electrode 62 is located above the channel region ‘B’ and on the organic insulating layer 61. The gate electrode 62 may be a metal single layer or metal multi-layers made of Cu, Mo, Ta, Cr, Ti, Al, Al alloy or the like.

A first passivation layer 71 is formed on the gate electrode 62. The passivation layer 71 may be made of an acryl-based photosensitive layer or silicon nitride layer. The first passivation layer 71 is removed from the contact hole 91 exposing the drain electrode 32. A second passivation layer (not shown) may be formed on the first passivation layer 71.

A pixel electrode 81 is formed on the first passivation layer 71. The pixel electrode 81 is made of a transparent electrically conductive material such as indium tin oxide (ITO) or indium zinc oxide (IZO) and is in contact with the drain electrode 32 through the contact hole 91.

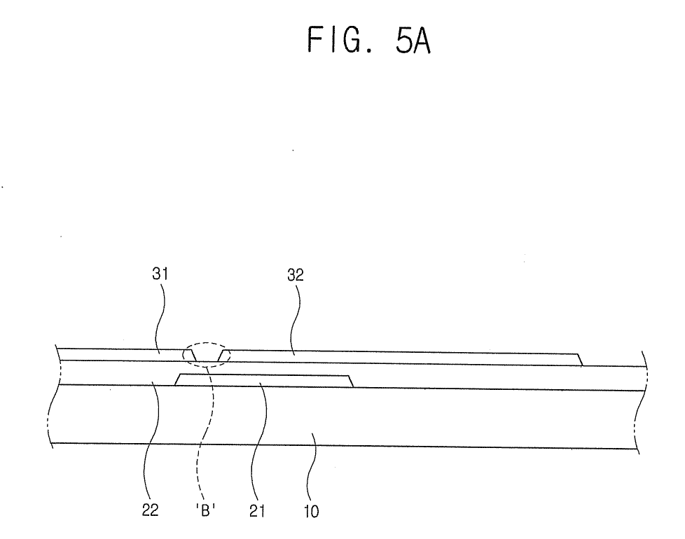

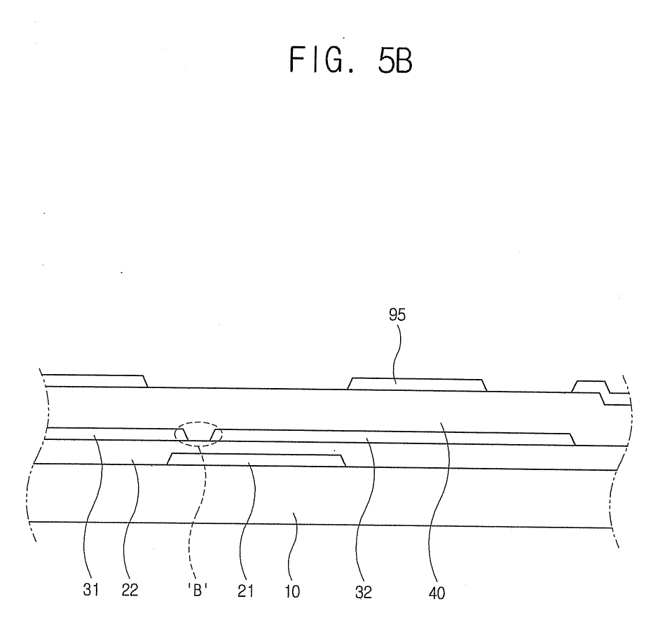

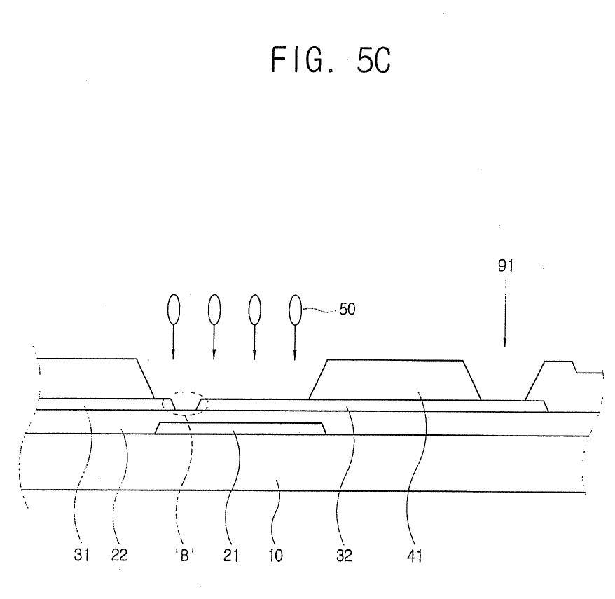

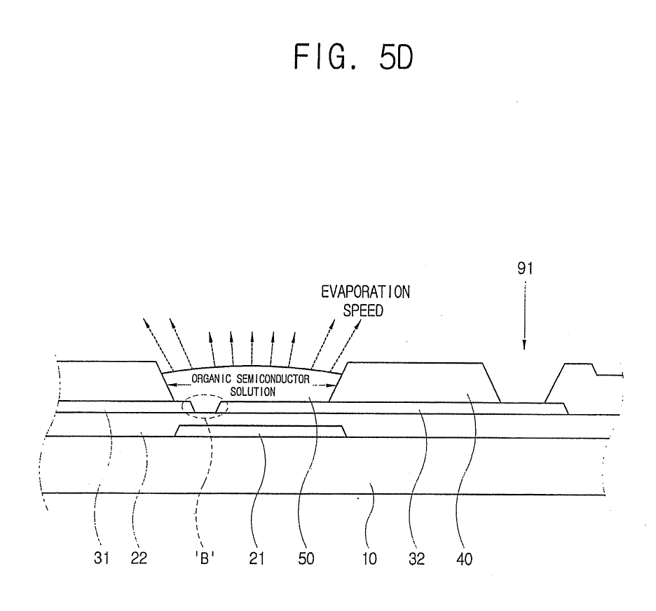

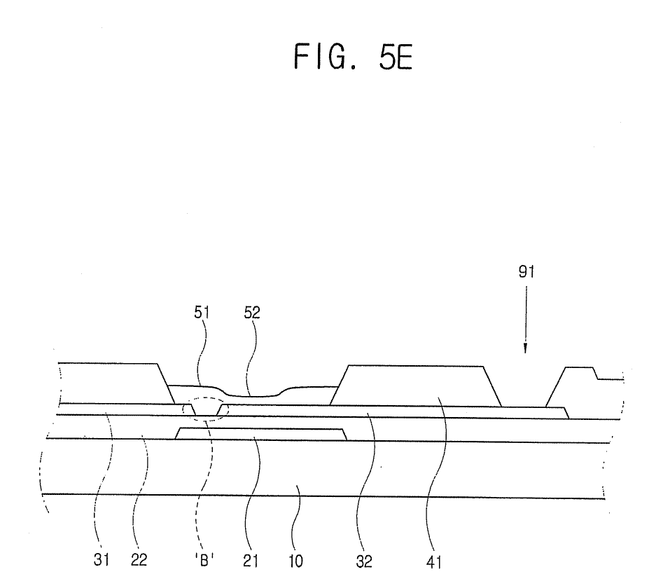

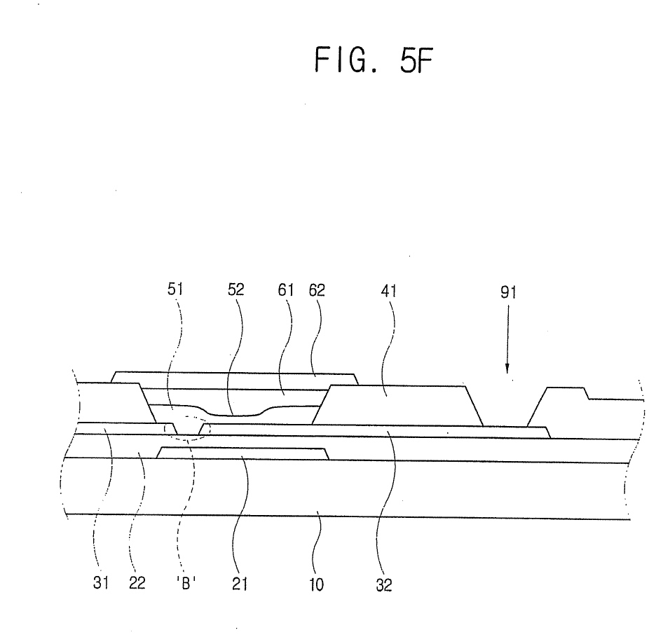

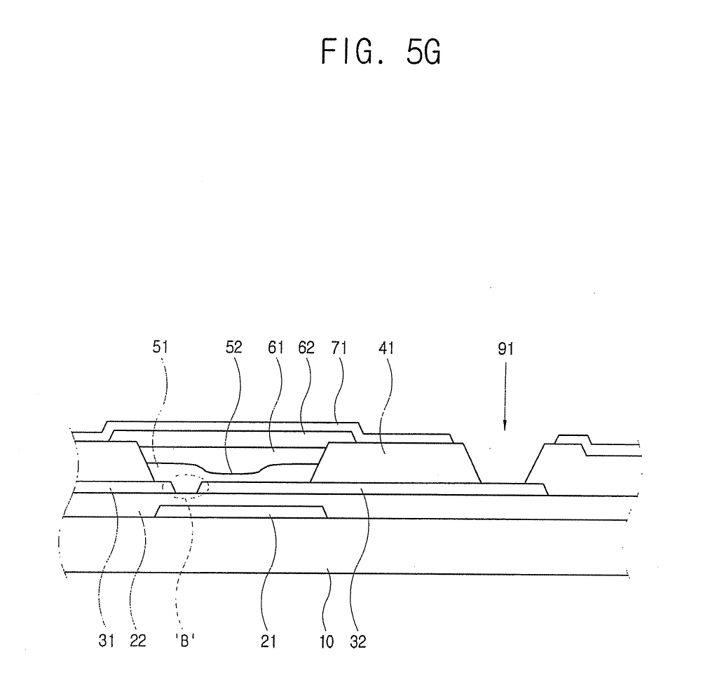

Hereinafter, an exemplary method of manufacturing the thin film transistor substrate according to the present invention will be described with reference to FIGS. 5A to 5G. FIGS. 5A to 5G illustrate an exemplary embodiment when the coffee stain phenomenon occurs, but are not limited thereto.

First, the light-blocking layer 21, the interposing insulating layer 22, the source electrode 31 and the drain electrode 32 are formed on the insulating substrate 10 as shown in FIG. 5A. The insulating substrate 10 can be made of glass, silicon or plastic.

The light-blocking layer 21 may be formed by performing the photolithography process after depositing a metal layer of, for example, Cr or MoW on the insulating substrate 10 by a sputtering method or the like.

In the case where the interposing insulating layer 22 is an organic layer, it may be formed by a spin coating or a slit coating method. However if the interposing insulating layer 22 is an inorganic layer, it may be formed by a chemical vapor deposition (“CVD”) method or a plasma enhanced chemical vapor deposition (“PECVD”) method.

The source electrode 31 and the drain electrode 32 can be formed through a photolithography process after depositing a metal layer on the insulating substrate 10 by a sputtering method or the like. The source electrode 31 and the drain electrode 32 are formed to create a space between each other, thus forming the channel region ‘B’. Although not shown, unlike the present embodiment, the source electrode 31 and the drain electrode 32 may be made of a transparent electrically conductive material such as ITO, IZO or the like, and the drain electrode 32 may be in one body with the pixel electrode 81.

Next, as shown in FIG. 5B, a bank coating layer 40 for forming the bank 41 is formed. A photosensitive layer pattern 95 is formed on the bank coating layer 40. The bank coating layer 40 can be formed by removing solvent after dissolving an organic polymer in the solvent and coating this solution by a slit coating method or a spin coating method. The photosensitive layer pattern 95 located on the bank coating layer 40 is located on portions of the bank coating layer 40 which are to become the bank 41. With such a configuration, portions of the bank coating layer 40 which are not covered by the photosensitive layer pattern 95 are etch-removed to form the bank 41.

In the case where the organic polymer of the bank 41 is photosensitive, the bank 41 may be formed without using the photosensitive layer pattern 95. That is, the bank 41 may be formed by exposing and developing the bank coating layer 40 using a mask. Further, the contact hole 91 exposing the drain electrode 32 is formed in the bank 41.

Next, as shown in FIG. 5C, an organic semiconductor solution 50 is dripped onto the channel region ‘B’ surrounded by the completed bank 41. The organic semiconductor solution 50 may be hydrophilic or oleophilic according to the solvent, and a portion thereof may be dripped onto side surfaces of the bank 41. As the bank 41 of the present invention is made of an organic polymer having features of water and oil repellency, the organic semiconductor solution 50 dripped onto the side surfaces of the bank 41 and flows down the side surfaces of the bank 41 into the channel region ‘B’. In contrast to the side surfaces of the bank 41, the interposing insulating layer 22, the source electrode 31 and the drain electrode 32 in contact with the organic semiconductor solution 50 do not have features of water and oil repellency. Therefore, the organic semiconductor solution 50 can be formed comparatively flat in the channel region ‘B’ and portions around it. Meanwhile, the organic semiconductor layer 53, or 51 and 52 may be formed by an evaporation method. In such a case, the bank 41 is unnecessary.

Next, as shown in FIG. 5D, the solvent is removed from the organic semiconductor solution 50 to form the organic semiconductor layer 53, or 51 and 52. After removing the solvent from the organic semiconductor solution 50, the organic semiconductor solution 50 has a shape including the peripheral portion 51 formed adjacent to the bank 41 and the depressed portion 52 lower than, and surrounded by, the peripheral portion 51 as shown in FIG. 5E.

This phenomenon, known as the coffee stain phenomenon, is one which results from when the organic semiconductor liquid 50 is jetted in the bank 41 and hardens, the organic semiconductor liquid 50 is stacked more in a peripheral portion since it moves outwards or to the peripheral portion due to the high evaporation speed of the peripheral portion of the surface of the organic semiconductor solution 50. That is, the coffee stain phenomenon causes the thickness difference in the organic semiconductor layer 53, or 51 and 52. If the channel region ‘B’ is located along a region where the thickness difference occurs, there is a problem in that the electrical characteristics of the thin film transistor are non-uniform.

Therefore, in the present invention, as described above, considering the coffee stain phenomenon, the source electrode 31 and the drain electrode 32 are formed such that the channel region ‘B’ is located in the peripheral portion 51 or the depressed portion 52 of the organic semiconductor layer 53. Herein, the surfaces of the peripheral portion 51 and the depressed portion 52 are comparatively flat, and thus the electrical characteristics of the thin film transistor are uniform.

Then, as shown in FIG. 5F, on the completed organic semiconductor layer 53, or 51 and 52, an organic insulating solution (not shown) is poured by an ink-jet method similar to the method for forming the organic semiconductor layer 53, or 51 and 52. Solvent is removed from the organic insulating solution (not shown) to form the organic insulating layer 61, which is also flat. The organic insulating layer 61 can be formed to be lower in height than the bank 41 by removing the solvent. The organic insulating layer 61 may also be formed through a slit or a spin coating and a patterning process using a photosensitive layer.

The gate electrode 62 is formed on the completed organic insulating layer 61. The gate electrode 62 may be formed through a lithography process after depositing a metal layer on the insulating substrate 10 by a sputtering method or the like. The gate electrode 62 may be a metal having a single layer or multi-layers.

Next, as shown in FIG. 5G, the first passivation layer 71 is formed on the gate electrode 62 and the bank 41. The first passivation layer 71 is removed from the contact hole 91. In the case where the first passivation layer 71 is a photosensitive organic layer, it may be formed by coating, exposing and developing. However, if it is an inorganic layer, such as silicon nitride, it may be formed through a deposition and a photolithography process. Further, the contact hole 91 exposing the drain electrode 32 is formed in the first passivation layer 71.

Then, the pixel electrode 81 is formed so as to be in contact with the drain electrode 32 through the contact hole 91 (see FIG. 2). Herein, the pixel electrode 81 is made of a transparent electrically conductive material such as ITO, IZO or the like.

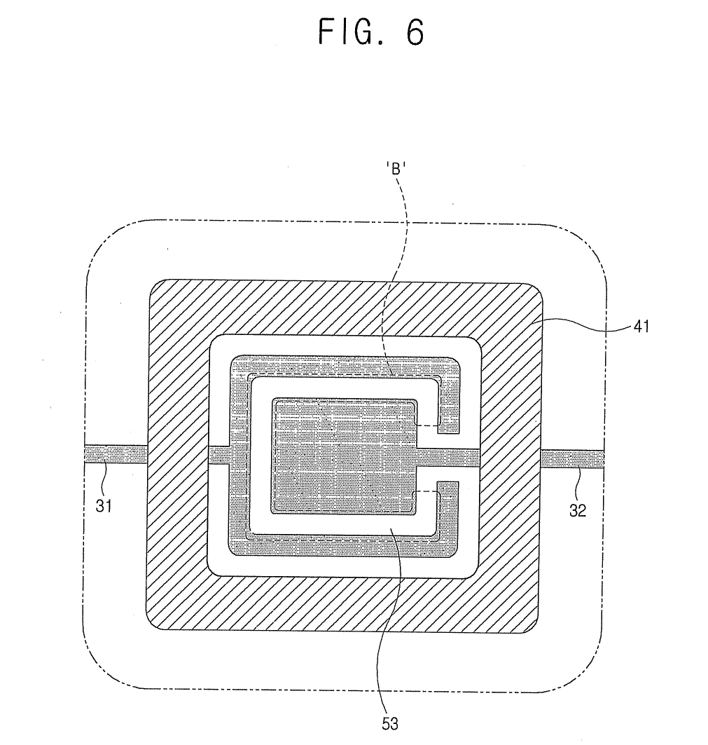

Hereinafter, a display device in accordance with an alternative exemplary embodiment of the present invention will be described with reference to FIG. 6. It should be noted that the following description only lists the features of this particular embodiment that are different from those described above, and that the remaining similar features are not described herein.

FIG. 6 is a top plan view of section ‘C’ as shown in FIG. 2 in accordance with an alternative exemplary embodiment. The drain electrode 32 and the source electrode 31 are interposed between the insulating substrate 10 and the organic semiconductor layer 53. The drain electrode 32 is extended from one side and expanded in width in a region where the organic semiconductor layer 53 is formed. The source electrode 31 is extended from another direction and formed along a periphery of the drain electrode 32 and spaced away from the periphery of the drain electrode 32. The end result is that the source electrode 31 is configured substantially as a capital letter ‘C’ with an extension from the left side of the C and that the drain electrode 32 forms a rectangle nearly filling the interior of the ‘C’ with an extension from the right side of the rectangle, as illustrated. The channel region ‘B’, which is defined as a gap formed between the source electrode 31 and the drain electrode 32, is biased to a periphery of the region in which the organic semiconductor layer 53 is formed. The channel region ‘B’ is located between the bank 41 and the drain electrode 32, as shown with dashed lines in FIG. 6. In a configuration in which the coffee stain phenomenon occurs the channel region ‘B’ may be formed so as to be located in the aforementioned peripheral portion, which leads to uniform electrical characteristics of the thin film transistor. Alternatively, the drain electrode 32 and the source electrode 31 may be formed in the depressed portion (not shown.)

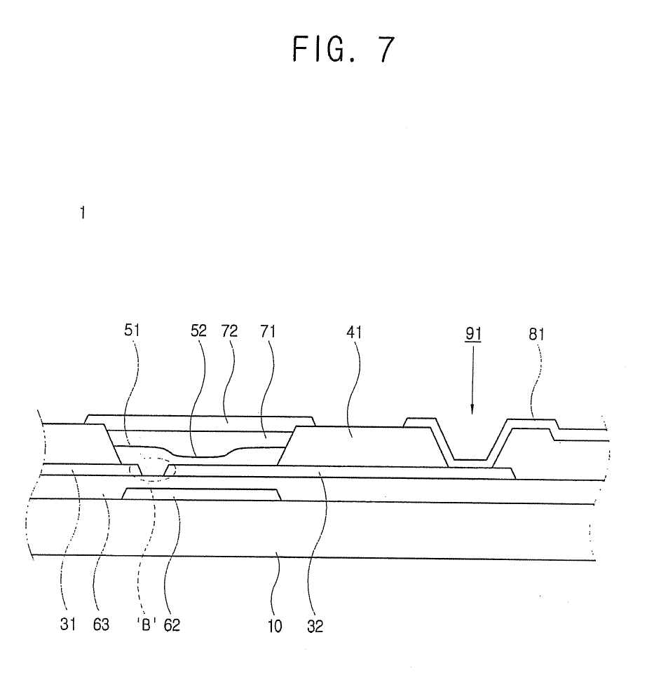

Hereinafter, a display device according to another exemplary embodiment of the present invention will be described with reference to FIG. 7. It should be noted that the following description only lists the features of this particular exemplary embodiment that are different from those described above, and the remaining similar features are not described herein. Further, the following description is provided under the assumption that the coffee stain phenomenon occurs, but it is not limited thereto.

Unlike the exemplary embodiment of FIG. 2, a display device 1 according to another exemplary embodiment shown in FIG. 7 is of a bottom gate type in which a gate electrode 62 is located under the organic semiconductor layer 53, or 51 and 52. As the gate electrode 62 blocks light incident on the lower portion of the insulating substrate 10, no separate light-blocking layer is formed. A gate insulating layer 63 is disposed between the gate electrode 62 and the organic semiconductor layer 53, or 51 and 52. The gate insulating layer 63 may be formed with an organic layer, an inorganic layer or a double layer of an organic and an inorganic layer.

According to the present exemplary embodiment, because only the first passivation layer 71 is formed after the formation of the organic semiconductor layer 53, or 51 and 52, there is less chance of deteriorating quality of the organic semiconductor layer 53, or 51 and 52 due to chemicals or plasma. The first passivation layer 71 may be formed in the bank 41 by an ink-jet method, and a second passivation layer 72 may be formed on the first passivation layer 71. The second passivation layer 72 may be formed with an organic layer using a coating method. Alternatively, the second passivation layer 72 may be formed with an inorganic layer by a deposition method.

The thin film transistor according to the present invention is applicable to a display device such as an LCD, an OLED or the like.

The OLED is a self light-emitting device using an organic material that emits light in response to electrical signals applied thereto. In the OLED, a negative electrode layer (pixel electrode), a hole injection layer, a hole transfer layer, a light-emitting layer, an electron transfer layer, an electron injection layer and a positive electrode layer (opposite electrode) are stacked. The drain electrode of the thin film transistor according to the present invention is electrically connected to the negative electrode layer to apply data signals thereto.

As described above, in accordance with the present invention, there is provided a display device which includes a thin film transistor with uniform electrical characteristics.

Further, there is provided a method of manufacturing a display device including a thin film transistor with uniform electrical characteristics.

Although a few exemplary embodiments of the present invention have been shown and described, it will be appreciated by those skilled in the art that changes may be made in these exemplary embodiments without departing from the principles and spirit of the invention, the scope of which is defined in the appended claims and their equivalents.

What is claimed is:

1. A display device, comprising:
an insulating substrate;
an organic semiconductor layer formed on the insulating substrate;
a source electrode; and
a drain electrode,
wherein the source electrode and the drain electrode are interposed between the insulating substrate and the organic semiconductor layer, and spaced away from each other to define a channel region therebetween which is biased to one side of a region in which the organic semiconductor layer is formed.

2. The display device according to claim 1, further comprising a bank formed on the source electrode and the drain electrode and forming an opening exposing the channel region, wherein the channel region is formed so as to be biased to one side of the opening, and the organic semiconductor layer is formed in the opening.

3. The display device according to claim 1, wherein the source electrode and the drain electrode extend substantially parallel to each other in the region in which the organic semiconductor layer is formed and extend in a perpendicular direction to an extension direction of extensions extending from the source electrode and the drain electrode.

4. The display device according to claim 1, wherein the organic semiconductor layer comprises a peripheral portion formed adjacent to the bank and a depressed portion surrounded by, and lower in height than, the peripheral portion, and the channel region is formed within the peripheral portion.

5. The display device according to claim 4, wherein a surface of the peripheral portion above the channel region is substantially flat.

6. The display device according to claim 4, wherein the source electrode and the drain electrode are made of indium tin oxide or indium zinc oxide.

7. The display device according to claim 4, wherein the organic semiconductor layer is formed by either one of an ink-jet method and an evaporation method.

8. The display device according to claim 4, further comprising:
a light-blocking layer located, corresponding to the organic semiconductor layer, between the insulating substrate and the source electrode and between the insulating substrate and the drain electrode; and
an interposing insulating layer covering the light-blocking layer.

9. The display device according to claim 8, further comprising:
an organic insulating layer covering the organic semiconductor layer; and
a gate electrode formed on the organic insulating layer.

10. The display device according to claim 1, further comprising:
a gate electrode located between the insulating substrate and the source electrode and between the insulating substrate and the drain electrode; and
a gate insulating layer covering the gate electrode.

11. A display device, comprising:
an insulating substrate;
an organic semiconductor layer formed on the insulating substrate;
a drain electrode and a source electrode interposed between the insulating substrate and the organic semiconductor layer,
wherein the drain electrode is extended from one direction to be expanded in width in a region in which the organic semiconductor layer is formed, the source electrode is extended from the other direction and formed along a periphery of the drain electrode and spaced away from the periphery of the drain electrode, and a channel region defined as a gap formed between the source electrode and the drain electrode is biased to either an interior portion or an exterior portion of the region in which the organic semiconductor layer is formed.

12. The display device according to claim 11, further comprising a bank formed on the source electrode and the drain electrode and forming an opening exposing the channel region, wherein the channel region is formed so as to be biased to either an interior portion or an exterior portion of the opening, and the organic semiconductor layer is formed in the opening.

13. The display device according to claim 12, wherein the channel region is provided in at least a portion of a space formed between the bank and the drain electrode.

14. The display device according to claim 12, wherein the organic semiconductor layer comprises a peripheral portion formed adjacent to the bank and a depressed portion surrounded by, and lower in height than, the peripheral portion, and the channel region is formed within at least a part of the peripheral portion.

15. The display device according to claim 14, wherein a surface of the peripheral portion above the channel region is substantially flat.

16. The display device according to claim 14, wherein the source electrode and the drain electrode are made of indium tin oxide or indium zinc oxide.

17. The display device according to claim 14, further comprising:
a light-blocking layer located, corresponding to the organic semiconductor layer, between the insulating substrate and the source electrode and between the insulating substrate and the drain electrode; and
an interposing insulating layer covering the light-blocking layer.

18. The display device according to claim 17, further comprising:
an organic insulating layer covering the organic semiconductor layer; and
a gate electrode formed on the organic insulating layer.

19. A display device, comprising:
an insulating substrate;
a source electrode and a drain electrode spaced away from each other to define a channel region;
a bank exposing at least one portion of the source electrode and at least one portion of the drain electrode and surrounding the channel region; and
an organic semiconductor layer formed in the bank with a surface of the organic semiconductor layer corresponding to the channel region being flat.

20. The display device according to claim 19, wherein the organic semiconductor layer comprises a peripheral portion formed adjacent to the bank and a depressed portion surrounded by, and lower in height than, the peripheral portion, and the channel region is formed corresponding to the peripheral portion in at least a portion of the peripheral portion.

21. The display device according to claim 20, wherein the organic semiconductor layer comprises a peripheral portion formed adjacent to the bank and a depressed portion surrounded by the peripheral portion and lower in height than the peripheral portion, and the channel region is formed within at least a portion of the depressed portion.

22. The display device according to claim 20, wherein the drain electrode is formed in a region corresponding to the depressed portion, and the source electrode is formed along a periphery of the drain electrode and corresponding to the periphery portion.

23. The display device according to claim 22, wherein the drain electrode extends into the periphery portion.

24. The display device according to claim 22, wherein the source electrode extends into the depressed portion.

25. A method of manufacturing a display device, comprising:
preparing an insulating substrate;
forming a source electrode and a drain electrode that are spaced away from each other to define a channel region therebetween;
forming a bank which exposes at least one portion of the source electrode and at least one portion of the drain electrode and surrounds the channel region; and
forming an organic semiconductor layer in the bank, with a surface of the organic semiconductor layer corresponding to the channel region being substantially flat.

26. The method of manufacturing a display device according to claim 25, wherein the organic semiconductor layer comprises a peripheral portion formed adjacent to the bank and a depressed portion surrounded by, and lower in height than, the peripheral portion.

27. The method of manufacturing a display device according to claim 26, wherein the source electrode and the drain electrode are formed such that the channel region is located in at least a portion of the peripheral portion.

28. The method of manufacturing a display device according to claim 26, wherein the source electrode and the drain electrode are formed such that the channel region is located in at least a portion of the depressed portion.

29. The method of manufacturing a display device according to claim 26, wherein the drain electrode is formed in a region corresponding to the depressed portion, and the source electrode is formed along a periphery of the drain electrode and corresponding to the periphery portion.

30. The method of manufacturing a display device according to claim 29, wherein the drain electrode is formed extending into the periphery portion.

31. The method of manufacturing a display device according to claim 29, wherein the source electrode is formed extending into the depressed portion.

32. The method of manufacturing a display device according to claim 25, wherein the organic semiconductor layer is formed by either one of an ink-jet method or an evaporation method.

33. The method of manufacturing a display device according to claim 25, further comprising:
forming an organic insulating layer on the organic semiconductor layer using an ink-jet method; and
forming a gate electrode on the organic insulating layer.

34. The method of manufacturing a display device according to claim 25, further comprising:
forming a light-blocking layer, corresponding to the organic semiconductor layer, between the insulating substrate and the source electrode and between the insulating substrate and the drain electrode; and
forming an interposing insulating layer covering the light-block layer.

35. The method of manufacturing a display device according to claim 25, further comprising:
forming a gate electrode between the insulating substrate and the source electrode and between the insulating substrate and the drain electrode; and
forming a gate insulating layer covering the light-block layer.

36. The method of manufacturing a display device according to claim 35, further comprising forming a passivation layer on the organic semiconductor layer using an ink-jet method.
